(19) United States
(12) Patent Application Publication
(10) Pub. No.: US 2020/0124939 A1
(43) Pub. Date: Apr. 23, 2020

(54) SHUTTER BLADE DEVICE FOR LITHOGRAPHY MACHINE

(71) Applicant: SHANGHAI MICRO ELECTRONICS EQUIPMENT (GROUP) CO., LTD., Shanghai (CN)

(72) Inventors: Yanfei WANG, Shanghai (CN); Guogan LIU, Shanghai (CN); Fuping ZHANG, Shanghai (CN); Xiang JIA, Shanghai (CN)

(21) Appl. No.: 16/628,981

(22) PCT Filed: Jul. 4, 2018
(86) PCT No.: PCT/CN2018/094462

§ 371 Date: Jan. 6, 2020

(30) Foreign Application Priority Data
Jul. 5, 2017 (CN) 201710543036.8

(51) Int. Cl. G03B 9/14; G03F 7/20

(52) U.S. Cl. CPC G03B 9/14; G03F 7/7055

(57) ABSTRACT

A shutter blade device for an exposure system of a lithography machine includes two shutter blades and two thermal insulation plates each attached to a respective one of the shutter blades. Attaching the thermal insulation plates to the respective shutter blades can hinder heat conduction from the blades to the rest of the shutter system, thus overcoming the problem of unstable performance or even burnout of the shutter system due to heat conduction from the shutter.

### TECHNICAL FIELD

The present invention relates to the technical field of semiconductor fabrication and, more specifically, to a shutter blade device for a lithography machine.

### BACKGROUND

Fabrication process of a semiconductor integrated circuit (IC) involves a plurality of steps including material preparation, masking, lithography, cleaning, etching, doping, chemical mechanical polishing, etc., with lithography being considered as the most crucial step that determines how advanced the whole process is.

Lithography is a technique for transferring a pattern from a photomask to a substrate with the aid of photoresist under light irradiation. It may mainly involve: firstly, irradiating the surface of the substrate coated with a thin photoresist layer with ultraviolet (UV) light by using a photomask, causing a chemical reaction in the exposed photoresist; then dissolving and removing the exposed or non-exposed photoresist using a development technique, thus replicating the photomask pattern in the thin photoresist layer; and finally, transferring the pattern into the substrate using an etching technique.

For lithography technology, the lithography machine used is most important because it directly determines the minimum critical dimension of the integrated circuit being fabricated.

In an exposure system of a lithography machine, the shutter has a direct influence to exposure dosage and dosage accuracy of the lithography machine. Therefore, the shutter is a most important part of the lithography machine. The control of the exposure dosage and dosage accuracy can be achieved by controlling the high-speed, high-frequency “opening/closing” actions of the shutter blades.

Exposure systems in existing med-end and low-end lithography machines typically employ high-pressure mercury lamps as light sources, in which exposure is enabled or disabled by a mechanical shutter disposed in the light path, and an exposure dosage is determined by the exposure time.

As the key components of such a shutter, shutter blades operate in a harsh environment where they are directly exposed to high heat and high ultraviolet radiation from the high-power mercury lamp. As the lifespan and heat conduction characteristics of the shutter blades directly influences the thermal environment of the shutter system as well as the shutter performance, frequent failure and burnout of the shutters in fabrication of ICs are directly related to blade overheating. In addition, since shutter blades are required to operate in conditions requiring high-speed, high-frequency rotation with quick “starting/stopping”, they must be lightweight, thin, long in service life and less deformable.

Shutter blades employed in existing med-end and low-end lithography machines are mostly made of thin metal sheets having undergone surface oxidation and have suffered from the following major problems:

(1) a high thermal conductivity of the blades tends to cause a change in thermal environment and hence performance of the shutter, possibly leading to failure in the control of exposure dosage and dosage accuracy, or even burnout of the shutter in the worst cases;

(2) large rotational inertia of the blades adversely affects the speed in “opening/closing” the shutters, making it impossible to provide low exposure doses;

(3) a low reflectance of the blades to high-energy ultraviolet light leads to a significant heat accumulation, easy deformability and short lifespan; and

(4) a large amount of compressed clean dry air (CDA) for cooling is required to be supplied with minor fluctuations, increasing the fabrication cost.

At present, it remains a challenge to solve the above problems effectively.

### SUMMARY OF THE DISCLOSURE

It is a main objective of the present invention to overcome the problem of unstable performance and even burnout of a shutter system arising from easy heat conduction across a shutter therein by presenting a shutter blade device.

To this end, the presented invention provides a shutter blade device, for an exposure system of a lithography machine, the shutter blade device comprising two shutter blades and two thermal insulation plates, wherein each of the shutter blades is attached to a corresponding one of the thermal insulation plates.

Optionally, a gap is provided between the two shutter blades along a direction of an optical axis of an incident light.

Optionally, when the two shutter blades are closed, the two shutter blades are partially overlapped along a direction perpendicular to an optical axis of an incident light.

Optionally, each of the shutter blades is made of an aluminum alloy.

Optionally, each of the shutter blades has a thickness ranging from 0.5 mm to 3 mm.

Optionally, each of the shutter blades has a light-receiving surface which is a smooth mirror surface to be irradiated by an incident light.

Optionally, the light-receiving surface has a surface roughness of 0.01 μm or less.

Optionally, the light-receiving surface is made by diamond cutting.

Optionally, each of the shutter blades has a light-receiving surface to be irradiated by an incident light, and a back surface opposite to the light-receiving surface and undergone a thinning processing.

Optionally, an area of the back surface which is corresponding to an area of the light-receiving surface to be irradiated by an incident light does not undergo a thinning processing or undergoes a thinning processing with lower degree than remaining areas.

Optionally, each of the shutter blades has a light-receiving surface to be irradiated by an incident light, and a back surface that is opposite to the light-receiving surface and is formed with one or more recesses.

Optionally, the one or more recesses are fan-shaped.

Optionally, the back surface is provided with one or more reinforcing ribs.

Optionally, the thermal insulation plates are fixedly attached to respective ends of the respective shutter blades by screws.

According to the present invention, attaching the thermal insulation plates to the respective shutter blades can hinder heat conduction from the blades to the rest of the shutter system, thus effectively overcoming the problem of unstable performance or even burnout of the shutter system due to the heat conduction from the shutter.

In addition, according to the present invention, through fabricating the blades from a low-density aluminum alloy and applying a suitable structurally lightweight blade design based on thinning to the back surfaces of the blades, effective reductions in weight and rotational inertia of the blades can be achieved, allowing a higher speed in “opening/closing” the blades, facilitating exposure at lower doses and enabling more accurate exposure dosage control. According to the present invention, by implementing the light-receiving surfaces of the blades as smooth mirror surfaces, reflectance of the blades to high-energy UV light can be significantly increased so that less heat will accumulate in the blades. As a result, the blades can experience less deformation and have an extended service life, resulting in savings in fabrication cost. Moreover, since less heat will accumulate in the blades, use of a smaller amount of compressed clean dry air (CDA) for cooling is allowed, thus further lowering the fabrication cost.

### BRIEF DESCRIPTION OF THE DRAWINGS

FIG. 1 is a front view of a shutter blade device according to an embodiment of the present invention.

FIG. 2 is a left view of a shutter blade device according to an embodiment of the invention.

FIG. 3 is a schematic structural diagram showing a shutter blade according to an embodiment of the invention.

FIG. 4 shows a UV light reflectance profile of conventional anodized blades.

FIG. 5 shows a UV light reflectance profile of shutter blades according to an embodiment of the invention.

FIG. 6 provides profiles each showing a relationship between the cooling clean dry air (CDA) flow rate and the blade temperature according to an embodiment of the invention.

In the figures, 1 denotes a screw; 2 denotes a thermal insulation plate; 3 denotes a shutter blade; 4 denotes a shutter blade; 5 denotes a UV light irradiation area; 6 denotes a threaded through hole; 7 denotes a recess resulting from thinning; 8 denotes an area which is not thinned or partially thinned; 9 denotes a reinforcing rib; and 10 denotes high-energy UV light.

### DETAILED DESCRIPTION

Specific embodiments of the present invention will be described in detail below with reference to the accompanying drawings. Note that the various figures are provided in a very simplified form not necessarily drawn to exact scale, the only intention of which is to facilitate convenience and clarity in explaining the embodiments.

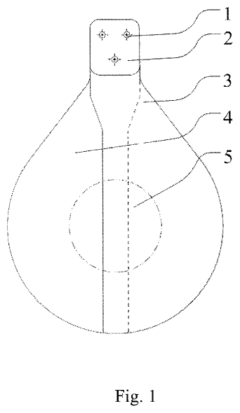

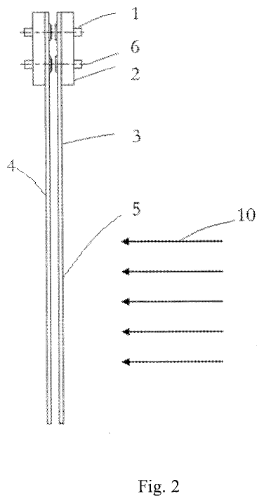

Referring to FIG. 1, in combination with FIG. 2, the present invention provides a shutter blade device composed of a first shutter blade 3, a second shutter blade 4 and two thermal insulation plates 2. During operation of the shutter blade device, high-energy ultraviolet (UV) light 10 directly irradiates the first and second shutter blades 3, 4, and thus a UV light irradiation area 5 with high energy and heat are formed on the first and second shutter blades 3, 4. The high-energy UV light 10 may be provided by a UV light source in an exposure system of a lithography machine. The UV light source may be a commonly-used high-pressure mercury lamp with many sharp spectral lines, in which only the G-line (at 436 nm) or I-line (at 365 nm) may be used, with all the others being filtered out. The high-energy UV light 10 may have high energy and be highly radioactive. When the high-energy UV light 10 irradiates the shutter blades 3, 4, the shutter blades 3, 4 may be under a harsh environment rich in heat and radiation. Heat will accumulate in the UV light irradiation area 5 of the shutter blades 3, 4 and then be spread across the whole shutter system. In order to reduce the heat conduction from the shutter blades 3, 4 to the whole shutter system and to maintain the stability for a thermal environment and performance of the shutter during operation, a thermal insulation plate 2 is attached to an end of each of the shutter blades 3, 4 by screws 1. The thermal insulation plate 2 may be formed of a material having heat insulation properties, such as glass fiber, nylon, acrylic resin, bakelite, polyacetal or, the like.

Optionally, there may be a gap between the first and second shutter blades 3, 4 along the direction of an optical axis of the incident high-energy UV light 10, which is preferred to be small and range from 1 mm to 6 mm. In this way, the contact between the first and second shutter blades 3, 4 and accordingly the wear of the first and second shutter blades 3, 4 during their movement can be avoided. Further, in a closed configuration of the two blades, there is an overlap between them along the direction perpendicular to the optical axis of the incident high-energy UV light 10, which may range from 1 mm to 15 mm and impart to the shutter blade device an increase ability to block the high-energy UV light 10.

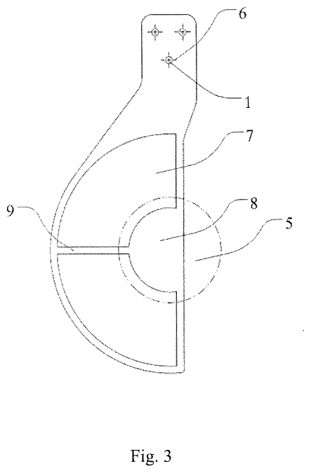

FIG. 3 shows one of the shutter blades according to the present invention. Since the first and second shutter blades 3, 4 are substantially mirrored to each other, only one of them will be explained below. In the aforesaid end of the shutter blade, several threaded through holes 6 may be defined, and each of the threaded through holes 6 is configured to receive a corresponding one of the screws 1 so that a corresponding one of the thermal insulation plates 2 can be fixedly attached to the shutter blade. According to the present invention, this fixed end of the shutter blade may be flexible and integral with the rest thereof, in order for the shutter blade to experience a reduced deformation when stressed. Optionally, according to the present invention, the shutter blades 3, 4 may be made of an aluminum alloy, which ensures that the blades not only have desired strength and rigidity but also feature a relatively low density and a light weight. Additionally, according to the present invention, each of the shutter blades 3, 4 may be a thin sheet having a light-receiving surface to be irradiated by the high-energy UV light 10, a back surface opposite to the light-receiving surface and a thickness generally of 0.5-3 mm. Those skilled in the art can make various modifications to the shapes of the first and second shutter blades 3, 4 according to this embodiment as actually desired, including making the first and second shutter blades 3, 4 not mirrored to each other anymore.

Optionally, as shown in FIG. 3, in each of the shutter blades 3, 4, the back surface may adopt a lightweight design, for example, with recesses 7 of various shapes resulting from thinning of the shutter blade. Of course, the recesses 7 may alternatively be of the same shape. In order to ensure desirable strength and rigidity of the blades 3, 4, they should not be excessively thinned from the side of the back surfaces and may be provided, as appropriate, on the same side with a number of reinforcing ribs 9. The reinforcing ribs 9 may be formed either concurrently with, or separately from, the formation of the recesses 7 in the back surfaces. In addition, considering that the UV light irradiation area 5 of the shutter blades 3, 4 is heated and has a higher temperature in the closed configuration of the shutter blades 3, 4, the shutter blades 3, 4 may be less, or not at all, thinned in the back area 8 opposite to the UV light irradiation areas 5. Therefore, according to a preferred embodiment, the recesses 7 formed in the back surfaces of the shutter blades 3, 4 may be fan-shaped. Further, regardless of whether the lightweight design is adopted or not, the back surfaces of the shutter blades are rough and have a higher roughness Ra of greater than 1.6 μm.

According to the present invention, each of the shutter blades 3, 4 can have a lowered density by fabricating it with an aluminum alloy and have a reduced volume by thinning it from its back surface. From I=∫ r²dm, which describes rotational inertia of a mass element dm of an object, it can be seen that since the mass element has a definite location in the object, its vertical distance r to the axis of rotation thereof is a fixed value, and the rotational inertia can be reduced by reducing the mass of the mass element dm. In addition, dm=ρdv, where ρ represents the density of the mass element and dv is the volume thereof. A proper reduction in rotational inertia of the shutter blades 3, 4 makes it possible for the shutter blades 3, 4 to be “opened/closed” at an increased speed and thus solves the problem caused from the low-dose exposure by the lithography machine.

Optionally, according to the present invention, the light-receiving surfaces of the shutter blades 3, 4 may be smooth mirror surfaces desired to have a surface roughness Ra of 0.01 μm or less. Typically, the smooth mirror surfaces may be made by a machining technique such as precise diamond cutting or chemical mechanical polishing, with the former being more commonly used. Machining a piece of a non-ferrous metal such as copper or aluminum by a natural single crystal diamond tool can result in an ultra-precision machined surface with dimensional accuracy on the order of 0.1 μm and a surface roughness Ra on the order of 0.01 μm. In this embodiment, the shutter blades 3, 4 are machined by precise diamond cutting. The surface roughness Ra was measured by an interferometer to be 0.006 μm, and nearly parallel diamond tool marks were clearly observed on the resulting surfaces at a certain magnification.

Surface finishing of the shutter blades 3, 4 may typically include the steps of: rough contour machining (e.g., water jet cutting, laser cutting, etc.); stress relief heat treatment; precise contour machining; processing of the flexible portions; stabilization heat treatment; fine grinding of the light-receiving surfaces for guaranteed flatness; diamond cutting of the light-receiving surfaces; formation of recesses in the back surfaces (if the lightweight design is adopted); grinding the back surfaces until a desired roughness thereof is obtained; processing the light-receiving surfaces by precise diamond cutting until a desired roughness thereof is obtained; and cleaning.

Experimental data show that reducing the roughness of the blade surfaces can result in a significant increase in their reflectance. The following description shows a surface reflectance comparison between a blade according to an embodiment of the invention and a conventional anodized blade that has not experienced precise diamond cutting.

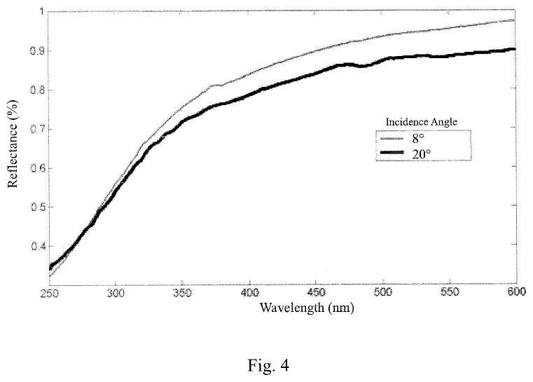

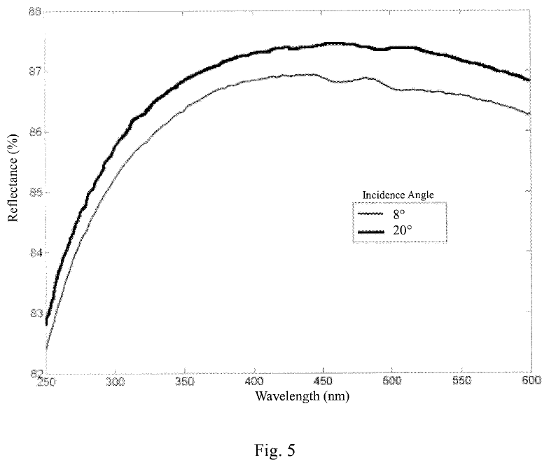

FIGS. 4 and 5 respectively shows surface reflectance profiles of the conventional and inventive anodized blades obtained using an ultraviolet-visible spectrophotometer at angles of incidence of 8° and 20°. As shown, in the UV spectrum, the reflectance of the conventional anodized blade is lower than 1% and decreases with the incident UV wavelength. By contrast, the reflectance of the inventive blade is higher than 80%, meaning that the inventive blade can reflect a major part of the incident energy and only absorb the remaining small part, thus having greatly reduced heat accumulation in the shutter blades 3, 4.

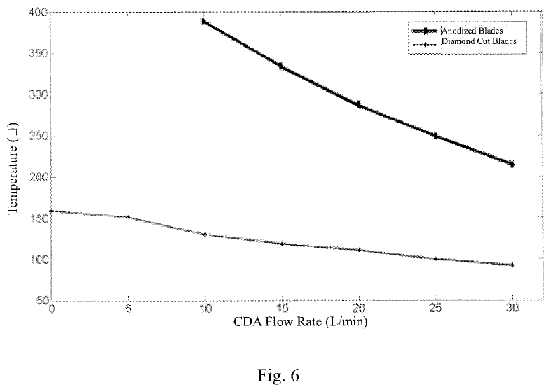

In addition to lower heat accumulation, the greater surface reflectance of the light-receiving surfaces of the shutter blades 3, 4 allows them to be heated at a lower rate, reducing the amount of compressed clean dry air (CDA) for cooling required to maintain a suitable thermal environment for ensuring stable operation of the shutter blades 3, 4. FIG. 6 provides profiles each showing a relationship between blade center temperature and CDA flow rate profile obtained at a power output of 2500 W of the mercury lamp. As shown, as the CDA rate decreased from 30 L/min to 10 L/min, the center temperature of the conventional anodized blade linearly increased from 250° C. to about 400° C. Moreover, when the CDA rate is decreased to 10 L/min, the anodized blade was burned out due to overheat. By contrast, the high-reflectance shutter blade of the present invention had its center temperature rise from 100° C. to 160° C. as the CDA rate decreased from 30 L/min to 0. Therefore, compared with the conventional anodized blade, the shutter blades 3, 4 according to the present invention allows less heat accumulation and thus less heat conduction to the shutter system. This can result in significantly improved operating stability of the shutter system. Further, when the CDA rate is decreased to 0 L/min, the shutter blade of the present invention has a center temperature of 160° C., much lower than the burnout temperature (400° C.) of the conventional anodized blade. This can reduce or even dispense with the use of CDA, leading to savings in fabrication cost.

In summary, in the shutter blade device provided in the embodiments disclosed herein, the thermal insulation plates can effectively block the heat of the blades to prevent from the heat conduction from the blades to the whole shutter system, which may impair the shutter performance or even lead to shutter burnout. Through fabricating the blades from a low-density, lightweight aluminum alloy and applying thereto a suitable structurally lightweight blade design (i.e., recesses formed in the blade by thinning), effective reductions in weight and rotational inertia of the blades can be achieved, allowing a higher speed in “opening/closing” the blades, exposure at lower doses and more accurate exposure dosage control. By implementing the light-receiving surfaces of the blades as smooth mirror surfaces, reflectance of the blades to high-energy UV light can be significantly increased so that less heat will accumulate in the blades. As a result, the blades can operate at a lower temperature, experience less deformation, have an extended service life and allow a lower replacement frequency, resulting in savings in fabrication cost. Moreover, since less heat will accumulate in the blades, heat conduction therefrom to the shutter system will be reduced. This is additionally helpful in maintaining a suitable thermal environment for the shutter system, which can facilitate performance stability thereof. Further, the reduced heat accumulation and lower operating temperature of the blades allow use of a smaller amount of compressed clean dry air (CDA) for cooling, thus further lowering the fabrication cost.

The embodiments presented above are merely several preferred examples and are in no way meant to limit the present invention. It is intended that any modifications such as equivalent alternatives or variations made to the subject matter or features thereof disclosed herein made by any person of ordinary skill in the art based on the above teachings without departing from the scope of the present invention are also considered to fall within the scope of the present invention.

1. A shutter blade device, for an exposure system of a lithography machine, the shutter blade device comprising two shutter blades and two thermal insulation plates, wherein each of the shutter blades is attached to a corresponding one of the thermal insulation plates.

2. The shutter blade device of claim 1, wherein a gap is provided between the two shutter blades along a direction of an optical axis of an incident light.

3. The shutter blade device of claim 1, wherein when the two shutter blades are closed, the two shutter blades are partially overlapped along a direction perpendicular to an optical axis of an incident light.

4. The shutter blade device of claim 1, wherein each of the shutter blades is made of an aluminum alloy.

5. The shutter blade device of claim 1, wherein each of the shutter blades has a thickness ranging from 0.5 mm to 3 mm.

6. The shutter blade device of claim 1, wherein each of the shutter blades has a light-receiving surface which is a smooth mirror surface to be irradiated by an incident light.

7. The shutter blade device of claim 6, wherein the light-receiving surface has a surface roughness of 0.01 μm or less.

8. The shutter blade device of claim 6, wherein the light-receiving surface is made by diamond cutting.

9. The shutter blade device of claim 1, wherein each of the shutter blades has a light-receiving surface to be irradiated by an incident light, and a back surface opposite to the light-receiving surface and undergone a thinning processing.

10. The shutter blade device of claim 9, wherein an area of the back surface which is corresponding to an area of the light-receiving surface to be irradiated by an incident light does not undergo a thinning processing or undergoes a thinning processing with lower degree than remaining areas.

11. The shutter blade device of claim 1, wherein each of the shutter blades has a light-receiving surface to be irradiated by an incident light, and a back surface that is opposite to the light-receiving surface and is formed with one or more recesses.

12. The shutter blade device of claim 11, wherein the one or more recesses are fan-shaped.

13. The shutter blade device of claim 11, wherein the back surface is provided with one or more reinforcing ribs.

14. The shutter blade device of claim 1, wherein the thermal insulation plates are fixedly attached to respective ends of the respective shutter blades by screws.

15. The shutter blade device of claim 2, wherein when the two shutter blades are closed, the two shutter blades are partially overlapped along a direction perpendicular to the optical axis of the incident light.

16. The shutter blade device of claim 2, wherein each of the shutter blades is made of an aluminum alloy.

17. The shutter blade device of claim 2, wherein each of the shutter blades has a thickness ranging from 0.5 mm to 3 mm.
